(19) United States
(12) Patent Application Publication
(10) Pub. No.: US 2021/0335606 A1
(43) Pub. Date: Oct. 28, 2021

(54) CONTINUOUS PLASMA FOR FILM DEPOSITION AND SURFACE TREATMENT

(71) Applicant: Lam Research Corporation, Fremont, CA (US)

(72) Inventors: Arul N. Dhas, Sherwood, OR (US); Tu Hong, Tualatin, OR (US); Changhe Guo, Tigard, OR (US); Ming Li, West Linn, OR (US)

(73) Assignee: Lam Research Corporation, Fremont, CA (US)

(21) Appl. No.: 17/250,979

(22) PCT Filed: Oct. 1, 2019
(86) PCT No.: PCT/US2019/054113

§ 371 Date: Apr. 6, 2021

Related U.S. Application Data
(60) Provisional application No. 62/744,055, filed on Oct. 10, 2018.

(51) Int. Cl. H01L 21/02; H01J 37/32; C23C 16/44; C23C 16/509

(52) U.S. Cl. CPC H01L 21/02274; H01L 21/0234; C23C 16/509; H01J 37/32146; C23C 16/4401; H01J 37/32449

(57) ABSTRACT

Disclosed are apparatuses and methods for flowing a reactant process gas into a processing chamber containing a substrate, generating a plasma at a first power level in the processing chamber during the flowing of the reactant process gas, thereby depositing a layer of a material on the substrate by plasma-enhanced chemical vapor deposition, maintaining the plasma while ceasing flowing the reactant process gas into the processing chamber, thereby stopping the depositing, without extinguishing the plasma, adjusting the plasma to a second power level, flowing an inert process gas into the processing chamber, thereby modifying the layer of the material while the plasma is at the second power level, and extinguishing the plasma after the modifying.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor fabrication often involves using plasma-enhanced chemical vapor deposition (“PECVD”) to deposit one or more layers of material onto a substrate and performing post-deposition processing using a plasma on the one or more deposited layers of material.

However, this conventional PECVD processing may result in substrate defects and slow throughput times. As a result, methods and techniques are sought to reduce the defects and improve substrate throughput.

### SUMMARY

In some embodiments, a method may be provided. The method may include flowing a reactant process gas into a processing chamber containing a substrate, generating a plasma at a first power level in the processing chamber during the flowing of the reactant process gas, thereby depositing a layer of a material on the substrate by plasma-enhanced chemical vapor deposition, maintaining the plasma while ceasing flowing the reactant process gas into the processing chamber, thereby stopping the depositing, without extinguishing the plasma, adjusting the plasma to a second power level, flowing an inert process gas into the processing chamber, thereby modifying the layer of the material while the plasma is at the second power level, and extinguishing the plasma after the modifying.

In some embodiments, the second power level may be greater than the first power level.

In some such embodiments, the first power level may be 400 Watts or greater and the second power may be 600 Watts or greater.

In some embodiments, the processing chamber may be at a constant pressure while generating the plasma.

In some embodiments, the constant pressure may be 2.1 Torr.

In some embodiments, the plasma may have a frequency of 13.56 MHz.

In some embodiments, purging the processing chamber may not be performed while generating the plasma.

In some embodiments, the method may further include purging the processing chamber after extinguishing the plasma.

In some embodiments, flowing the reactant process gas may further include flowing the reactant process gas into the processing chamber containing a plurality of substrates, generating the plasma at the first power level may further include simultaneously depositing the layer of the material on the plurality of substrates by plasma-enhanced chemical vapor deposition, maintaining the plasma while ceasing flowing the reactant process gas may further include stopping the depositing on the plurality of substrates without extinguishing the plasma, and flowing the inert process gas may further include modifying the layer of the material on the plurality of substrates while the plasma is at the second power level.

In some such embodiments, the plurality of substrates may not be transferred within the processing chamber during the flowing the reactant process gas, the generating, the maintaining, and the flowing the inert process gas.

In some such embodiments, the method may further include transferring the plurality of substrates into the processing chamber before flowing the reactant process gas, and transferring the plurality of substrates out of the processing chamber after extinguishing the plasma.

In some embodiments, modifying the layer of material may include removing nitrogen bonds, changing the surface roughness of the layer, changing the refractory index of the layer, changing the composition of the layer, and changing the stress of the layer.

In some embodiments, an apparatus may be provided. The apparatus may include a processing chamber, a first process station that includes a first substrate support, the first substrate support being configured to position a first substrate in the processing chamber, a process gas unit configured to flow a reactant process gas and an inert process gas onto the first substrate supported by the first substrate support, a plasma source configured to generate a plasma at a first power level and a second power level in the first process station, and a controller. The controller may include instructions that are configured to flow the reactant process gas onto the first substrate that is supported by the first substrate support, generate, while the reactant process gas is flowed onto the first substrate that is supported by the first substrate support, the plasma at the first power level in the first process station to thereby deposit a layer of a material on the first substrate by plasma-enhanced chemical vapor deposition (PECVD), stop the deposition of the layer of the material on the first substrate by ceasing the flow of the reactant process gas onto the first substrate, maintain the plasma during and after the deposition is stopped, without extinguishing the plasma, adjust the plasma to a second power level while the plasma is maintained, flow the inert process gas onto the first substrate to thereby modify the layer of the material while the plasma is maintained at the second power level, and extinguish the plasma after the layer of the material is modified.

In some embodiments, the first power level may be 400 Watts or greater and the second power may be 600 Watts or greater.

In some embodiments, the apparatus may further include a vacuum pump configured to control a pressure in the processing chamber, and the controller may further include instructions that are configured to maintain the processing chamber at a constant pressure while the plasma is generated in the processing chamber.

In some such embodiments, the constant pressure may be at least 2.1 Torr.

In some such embodiments, the vacuum pump may further be configured to evacuate the processing chamber, and the controller may further include instructions that are configured to purge the processing chamber after the plasma is extinguished.

In some embodiments, the plasma source may be configured to generate the plasma at a frequency of 13.56 MHz.

In some embodiments, the apparatus may further include a second process station. The second process station may include a second substrate support, the second substrate support is configured to position a second substrate in the processing chamber, the process gas unit may be further configured to flow the reactant process gas and the inert process gas onto the second substrate supported by the second substrate support, the plasma source may be further configured to generate the plasma in the second process station, and the controller may further include instructions that are configured to simultaneously flow the reactant process gas onto the first substrate and the second substrate that is supported by the second substrate support, generate, while the reactant process gas is simultaneously flowed onto the first substrate and the second substrate, the plasma at the first power level in the first process station and in the second process station to thereby deposit a layer of a material on the first substrate and on the second substrate by PECVD, stop the deposition of the layer of the material on the first substrate and the second substrate by ceasing the flow of the reactant process gas onto the first substrate and onto the second substrate, maintain the plasma during and after the deposition is stopped on the first substrate and onto the second substrate, without extinguishing the plasma, simultaneously flow the inert process gas onto both the first substrate and onto the second substrate to thereby modify the layer of the material on the first substrate and the second substrate while the plasma is maintained at the second power level, and extinguish the plasma after the layer of the material is modified.

In some embodiments, the reactant process gas may include a silicon.

In some such embodiments, the reactant process gas may include a silane.

In some such embodiments, the reactant process gas may include a tetra-ethoxy-silane.

In some such embodiments, the reactant process gas may include a tetra-methyl-silane.

In some embodiments, the inert process gas may include N₂O.

### BRIEF DESCRIPTION OF THE DRAWINGS

FIG. 1 depicts a table of a common PECVD process.

FIG. 2 depicts an example process flow diagram for performing operations in accordance with disclosed embodiments.

FIG. 3 depicts a second example process flow diagram for performing operations in accordance with disclosed embodiments.

FIG. 4 depicts a table for performing operations in accordance with disclosed embodiments.

FIG. 5 provides a block diagram of an example apparatus that may be used to practice the disclosed embodiments.

FIG. 6 shows a schematic view of an embodiment of a multi-station processing tool.

FIG. 7 depicts a table of defect counts for processed substrates.

FIG. 8 depicts normalized thickness profiles of two processed substrates.

FIG. 9 depicts normalized reflective index profiles for the two processed substrates.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry may have a diameter of 200 mm, or 300 mm, or 450 mm. The following detailed description assumes the invention is implemented on a wafer. However, the invention is not so limited. The work piece may be of various shapes, sizes, and materials. In addition to semiconductor wafers, other work pieces that may take advantage of this invention include various articles such as printed circuit boards, glass panels, and the like.

Plasma-Enhanced Chemical Vapor Deposition

Many semiconductor fabrication processes deposit materials using plasma-enhanced chemical vapor deposition (“PECVD”). In a typical PECVD reaction, a substrate is exposed to one or more volatile precursors which react and/or decompose to produce the desired deposit on the substrate surface. The PECVD process generally begins by flowing one or more reactants into the reaction chamber. The reactant delivery may continue as a plasma is generated which exposes the substrate surface to the plasma, which in turn causes deposition to occur on the substrate surface. This process continues until a desired film thickness is reached, after which the plasma is generally extinguished and the reactant flow is terminated. Next, the reaction chamber may be purged and post-deposition steps may be performed.

The various post-deposition steps may include surface treatments of one or more deposited layers in order to prepare the one or more layers for subsequent processing. These post-deposition surface treatments may include modifying the one or more deposited layers, such as removing nitrogen bonds in the layers, changing the surface roughness of the layers, changing the composition, changing the refractive index (RI)/transparency of the layers (k, extinction coefficient), and changing the stress of the layers. Many of these surface treatments may use a plasma that is generated in the PECVD chamber. For example, PECVD may be used to deposit an optical layer that includes a layer of silicon-oxynitride (SiON) or other reflective material, onto which a photoresist may later be deposited for even later processing, such as etching. In order to assist the deposition of the photoresist onto the optical layer that was deposited via PECVD, a post-deposition surface treatment may include flowing a nitrous oxide (N₂O) and generating a N₂O plasma that may remove any ammonium-based bonds on the one or more layers.

For many PEVCD processes and post-deposition steps that use plasma, the plasma is typically turned off after the PECVD deposition and turned back on for one or more of these post-deposition steps. The plasma is turned off for various reasons. For example, the PECVD deposition may be performed at one pressure while the post-deposition steps are performed at a different pressure, and it is advantageous to turn off the plasma when adjusting the pressure because of plasma stability concerns. Additionally, for multi-station processing chambers, various hardware and plasma limitations generally require that the plasma be turned off between the PECVD deposition and the post-deposition steps. For instance, many multi-station PECVD processing chambers simultaneously generate a plasma at each station during deposition, but generally perform the post-deposition steps at only some of the stations, such as at only one station. Because of the hardware and plasma limitations of multi-station apparatuses, it is generally difficult or not possible to turn-off the plasma at some of the stations while maintaining the plasma at others, and even if the plasma is maintained at some stations, the plasma may not have the desired characteristics for the post deposition steps. The multi-station PECVD chamber may also turn off the plasma because of the different pressures utilized during the PECVD deposition and the post-deposition steps.

Although turning off the plasma after PECVD deposition and then turning the plasma back on for some post-deposition steps is advantageous, and sometimes required, there are additional disadvantages associated with this turning off and on of the plasma. For instance, when a plasma is generated during PECVD deposition, particles and other contaminants are suspended within the plasma and when the plasma is turned off, these particles and contaminants tend to land on the substrate which can contaminate the substrate and ultimately cause substrate defects. Because of this, a purge of the chamber can be performed after the deposition and extinguishment of the plasma, and before the re-ignition of the plasma in order to remove the previously suspended particles and contaminants. However, some contamination and defects of the substrate generally still occur even with this purge. Additionally, this purge increases the total processing time of a substrate which is undesirable. Similarly, reigniting the plasma increases the processing time because additional steps are typically performed to ignite the plasma, such as charging the gas line (i.e., flowing gas from a gas source to the chamber), power application to the chamber or station, and plasma stabilization (i.e., allowing the plasma to stabilize and confirming it is stable), all of which increase the processing time of the substrate, which negatively affects throughput time. In instances when the pressure is changed between the PECVD deposition and the post-deposition steps, additional time may also be added for this pressure adjustment which again negatively affects throughput.

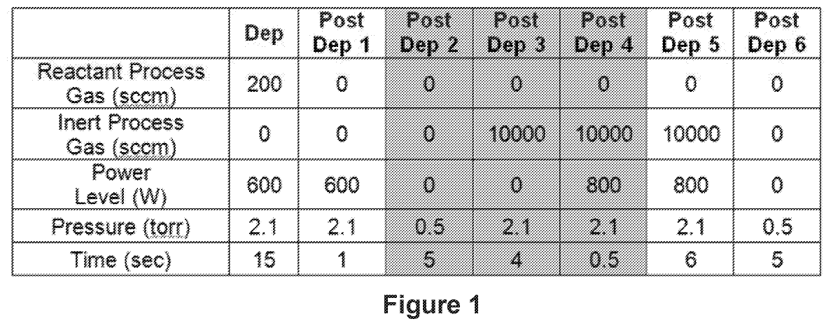

FIG. 1 depicts a table of a common PECVD process. The first column on the left indicates the process conditions while each column after that from left to right indicates a sequential step in the PECVD processing. As described, this is an example of a typical PECVD processing that turns off the plasma after deposition and turns the plasm back on for some post-deposition processing steps. Here, the deposition step (“Dep”) involves flowing the reactant process gas onto a substrate in a processing chamber while a plasma is generated at a first power level (600 Watts) while the pressure is at a first pressure (2.1 Torr) for 15 seconds in order to deposit a layer of material on the substrate. In a first post-deposition step (“Post Dep 1), for 1 second the reactant flow may be stopped but the plasma may remain on, and in a second post-deposition step (“Post Dep 2”), the plasma is turned off and a purge (or pump to base) operation is performed for 5 seconds in order to remove particles from the chamber; the pressure is lowered to 0.5 Torr during this step. In a third post-deposition step (“Post Dep 3”), a second process gas, which may be an inert gas, is flowed to the substrate which has a line charge time, such as 4 seconds, for the second process gas to reach the substrate; this step also involves increasing the pressure back to 2.1 Torr. In a fourth post-deposition step (“Post Dep 4”), the plasma is ignited and is at a second power level (800 W) while the inert process gas is flowing to the substrate and the plasma may be allowed to stabilize for a stabilizing time, such as 0.5 seconds. In some instances, the pressure of the chamber may be adjusted before the fourth post-deposition to a pressure that is different than the pressure of the deposition and is more desirable for the post-deposition plasma or processes. A fifth post-deposition step (“Post Dep 5”) may include maintaining the plasma while the second process gas is flowing to the substrate in order to perform one or more surface treatments described above that modify the surface of the deposited material; this may occur for any desirable time, such as 6 seconds. In a sixth post-deposition step, another pump to base operation may be performed similar to Post Dep 2 in order to remove particles and gases from the chamber.

The above example PECVD process may be implemented in a single station or multi-station chamber. In those instances of a single station, all of the pre-deposition, deposition, and post-deposition steps are performed as the substrate remains in the chamber at the single station. In some of the instances of a multi-station chamber, deposition may occur at multiple chambers, and the post-deposition steps may occur at just one station. For example, for a chamber that includes four stations and a substrate at each station, a layer of material may be deposited simultaneously on the four substrates by simultaneously flowing the reactant to each of the substrates and simultaneously generating the plasma at each of the stations. In FIG. 1, the “Dep” step may be performed at all four stations. In Post Dep 1, similar to above, the reactant process gas flow may be stopped to all four stations but the plasma may remain on at all stations for a period of time, and in Post Dep 2, the plasma is turned off in each station and a purge operation is performed in order to remove particles and other gases from all stations. As described above, the post-deposition surface treatments may be performed at less than all of the stations, such as just one station, and for this example process, Post Dep 3, 4, and 5 may be performed at just one station. This includes generating and maintaining the plasma in just that one station. As stated above, these example implementations may non-advantageously increase throughput time and increase substrate defects.

Continuously Maintaining a Plasma During Deposition and Post-Deposition Processing

The present disclosure includes techniques and apparatuses for continuously maintaining a plasma in a processing chamber during and throughout PECVD deposition and post-deposition steps. As described further below, these techniques and apparatuses increase substrate throughput (i.e., reduce processing time) and also reduce substrate defects.

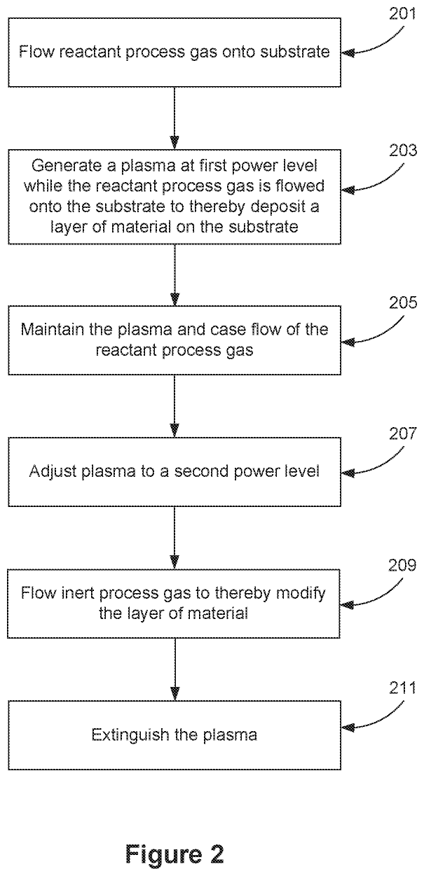

FIG. 2 depicts an example process flow diagram for performing operations in accordance with disclosed embodiments. In operation 201, a reactant process gas is flowed onto a substrate that is positioned within a processing chamber. As described herein, the substrate may be positioned on a wafer support structure, such as a pedestal or electrostatic chuck. The processing chamber is part of a semiconductor processing tool (“tool”), and the tool, as described below, is configured to flow the reactant process gas onto the substrate in the processing chamber. In some embodiments, the operations of FIG. 2 may be performed in a single-station processing chamber while in other embodiments, the operations of FIG. 2 may be performed in a multi-station processing chamber. In the multi-station processing chamber embodiments, each station may have a substrate positioned at the station, such as on a pedestal in that station, and operation 201 simultaneously flows a reactant process gas to each substrate at each station.

Examples of reactants used for PECVD will now be discussed. At least one of the reactants will generally contain an element that is solid at room temperature, the element being incorporated into the film formed by the PECVD method. This reactant may be referred to as a principal reactant. The principal reactant typically includes, for example, a metal (e.g., aluminum, titanium, etc.), a semiconductor (e.g., silicon, germanium, etc.), and/or a non-metal or metalloid (e.g., boron). The other reactant is sometimes referred to as an auxiliary reactant or a co-reactant. Non-limiting examples of co-reactants include oxygen, ozone, hydrogen, hydrazine, water, carbon monoxide, nitrous oxide, ammonia, alkyl amines, and the like. The co-reactant may also be a mix of reactants, as mentioned above.

The PECVD process may be used to deposit a wide variety of film types and in particular implementations to fill gaps with these film types. Some may be used to form undoped silicon oxides, other film types such as nitrides, carbides, oxynitrides, carbon-doped oxides, nitrogen-doped oxides, borides, etc. may also be formed. Oxides include a wide range of materials including undoped silicate glass (USG), doped silicate glass. Examples of doped glasses included boron doped silicate glass (BSG), phosphorus doped silicate glass (PSG), and boron phosphorus doped silicate glass (BPSG). Still further, the PECVD process may be used for metal deposition and feature fill.

In certain embodiments, the deposited film is a silicon-containing film. In these cases, the silicon-containing reactant may be for example, a silane, a halosilane or an aminosilane. A silane contains hydrogen and/or carbon groups, but does not contain a halogen. Examples of silanes are silane (SiH₄), tetramethylsilane (C₄H₁₂Si; 4MS) disilane (Si₂H₆), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, tetra-ethyl-ortho-silicate (also known as tetra-ethoxy-silane or TEOS) and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH3)₂)₂, (Si(CH₃)₂NH)₃ and the like. A further example of an aminosilane is trisilylamine (N(SiH₃)).

In other cases, the deposited film contains metal. Examples of metal-containing films that may be formed include oxides and nitrides of aluminum, titanium, hafnium, tantalum, tungsten, manganese, magnesium, strontium, etc., as well as elemental metal films. Example precursors may include metal alkylamines, metal alkoxides, metal alkylamides, metal halides, metal ß-diketonates, metal carbonyls, organometallics, etc. Appropriate metal-containing precursors will include the metal that is desired to be incorporated into the film. For example, a tantalum-containing layer may be deposited by reacting pentakis(dimethylamido)tantalum with ammonia or another reducing agent. Further examples of metal-containing precursors that may be employed include trimethylaluminum, tetraethoxytitanium, tetrakis-dimethyl-amido titanium, hafnium tetrakis(ethylmethylamide), bis(cyclopentadienyl)manganese, bis(n-propylcyclopentadienyl)magnesium, etc.

In certain implementations, an oxygen-containing oxidizing reactant is used. Examples of oxygen-containing oxidizing reactants include oxygen, ozone, nitrous oxide, carbon monoxide, etc.

In some embodiments, the deposited film contains nitrogen, and a nitrogen-containing reactant is used. A nitrogen-containing reactant contains at least one nitrogen, for example, ammonia, hydrazine, amines (e.g., amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

Other precursors, such as will be apparent to or readily discernible by those skilled in the art given the teachings provided herein, may also be used.

For example, in one embodiment, the PECVD reaction is performed with TEOS, 4MS, or a silane. The TEOS, 4MS, and silane reactants have been found to be especially useful in practicing the PECVD reaction.

The flow rate of reactants may vary depending on the desired process. In one embodiment related to PECVD undoped silicate glass (USG), SiH₄ is used as a reactant and has a flow rate between about 100-1,500 sccm, with a flow of N₂O between about 100-20,000 sccm. In another embodiment related to PECVD using TEOS, the flow of TEOS is between about 1-20 mL/min, and the flow of O₂ is between about 100-30,000 sccm.

Returning to FIG. 2, in operation 203, a plasma is generated in the processing chamber while the reactant is flowing onto the substrate which in turn causes a layer of material to be deposited onto the substrate by PECVD. For single-station embodiments, operation 203 generates the plasma in the processing chamber for the single station. In the multi-station embodiments, operation 203 simultaneously generates the plasma in each station. The simultaneous flowing of the reactant process gas and plasma generation causes the PECVD reaction that in turn causes deposition of the layer of material onto the substrate.

The PECVD reactions are driven by exposure to plasma. The plasma may be a capacitively coupled plasma or a remotely generated inductively coupled plasma.

The gas used to generate the plasma during PECVD will include at least one reactant described above. The plasma generation gas may also include other species, as well. For example, in certain embodiments the plasma generation gas includes an inert gas.

In some implementations, the frequency used to drive plasma formation during the PECVD of operation 203 may only contain a high frequency (“HF”) component and not a low frequency (“LF”) component. The HF frequency may be about 13.56 MHz or about 27 MHz. The HF RF power used to drive plasma formation may be between about 200-3,000 W. These power levels represent the total power delivered, which may be divided among the stations in a multi-station processing chambers. For instance, as noted in FIG. 2, the plasma is generated at a first power level which may be any power within this range, such as 600 W for a single station or 2,400 W for a four-station processing chamber which results in 600 W for each of the four stations. The duration of plasma exposure depends on the desired thickness of the deposited film. In some embodiments, pulsed PECVD methods may be used. These methods may involve pulsing precursor and/or RF power levels.

In some embodiments, the post-deposition treatments use only a HF plasma and for these embodiments, using a plasma that has only a HF component during deposition enables the plasma to be maintained and utilized during the deposition and post-deposition processing steps.

In some other embodiments, the frequency used to drive plasma formation during PECVD may contain both LF and HF components. The LF frequency may be between about 300-400 kHz. The LF RF power used to drive plasma formation may be between about 200-2,500 W. In some embodiments, the post-deposition treatments use only a plasmas with both HF and LF components and in these embodiments, using a plasma that has LF and HF components during deposition enables the plasma to be maintained and utilized during the deposition and post-deposition processing steps.

In the embodiments described herein, the plasma is continuously maintained after the PECVD deposition and during the post-deposition steps; the plasma is not extinguished after the deposition and then reignited for the post-deposition steps like in conventional PECVD processes described above. Therefore, as seen in FIG. 2, once the desired layer of material is deposited in operation 203, the PECVD deposition process is stopped by ceasing the flow of the reactant process gas and the plasma is maintained, it is not extinguished, in operation 205. In the multi-station processing chamber embodiments, the plasma is continuously maintained in all of the stations; the plasma is not extinguished in any station.

The continuously maintained plasma can then be used for various post-deposition processes. In some embodiments, the power of the plasma used in the post-deposition processes is different than the power of the plasma during PECVD deposition. In these embodiments, operation 207 may be performed which adjusts the plasma to a second power level, that is different than the first power level. This power is again between about 200-3,000 W. In some embodiments, the second power level may be greater than the first power level. For instance, the first power level may be greater than 400 W, such as 600 W, and the second power level may be greater than 600 W, such as 800 W. In other embodiments this optional operation 207 may not be needed because the plasma during deposition and during the post-deposition steps may be the same. In some embodiments, the continuously maintained plasma after the PECVD deposition may have the same HF frequency as used during the PECVD deposition, such as 13.56 MHz while in other embodiments the frequency components of the plasma used during and after the deposition may be different. As noted above, in some embodiments, using a HF plasma during the deposition and the post-deposition treatments enables the continuous generation and use of a plasma during these deposition and post-deposition processing steps.

After operation 205, and after operation 207 if it is performed, an inert gas is flowed onto the substrate while the plasma is still maintained in order to perform a surface treatment that modifies the layer of material. In some embodiments in which operation 207 is performed, this modification occurs while the plasma is at the second power level. As stated above, these surface treatments, or modifications, include removing nitrogen bonds in the layers, changing the surface roughness of the layers, changing the composition, changing the reflective index (RI)/transparency of the layers, and changing the stress of the layers. These treatments are performed using a combination of the continuously maintained plasma and a flow of an inert process gas or mixtures, such as N₂O. In the multi-station processing chamber embodiments, the inert process gas is simultaneously flowed to each of the substrates in all of the stations which simultaneously modifies, or performs a surface treatment of, the layer of material on each substrate in all of the stations.

The flow rate of the inert process gas may be between about 100-30,000 sccm. For example, a flow of N₂O may be between about 100-20,000 sccm and a flow of O₂ may be between about 100-20,000 sccm.

After the post-deposition steps are performed in operation 209, the plasma may be extinguished in operation 211. After operation 211, the processing chamber may be purged, i.e., a pump to base operation is performed. This may remove unwanted byproducts, contaminants, gases, and particles from the processing chamber. In some embodiments, unlike conventional PECVD processing, a purge operation is not performed after the deposition of 203 and before the post-deposition processing of operation 209. Instead, in the embodiments of FIG. 2, a purge is only performed after the post-deposition steps are completed and not during or between operations 203, 205, 207, and 209. The pressure of the purge operation is generally lower than the deposition and post-deposition steps, such as 0.5 Torr.

As noted above, once the plasma is generated in operation 203, the plasma is maintained and not extinguished during and through operations 205, 207, and 209. During this continuous maintenance, the plasma may have the same frequency, such as 13.56 MHz. For some embodiments for multi-station processing chambers, during this continuously maintained plasma the substrates are not transferred within the processing chamber during operations 203 through 211, i.e., the substrates remain at a single station during the flowing the reactant process gas and the plasma generation, after the deposition is stopped and the plasma is maintained, during the plasma power adjustment, and during the post-deposition process of modifying the layer of material on the substrate.

In some embodiments, prior to operation 201, a substrate loading operation may be performed which loads one or more substrates into the processing chamber. For instance, in the single-station embodiments, this includes loading just one substrate into the single station; in the multi-station embodiments, this includes loading one or more substrates into the processing chamber, such as loading one substrate into each of the stations. Similarly, after operation 211 there may be a substrate unloading operation which removes the one or more substrates from the processing chamber, such as the one substrate from the single station, or all of the substrates from all of the stations in multi-station embodiments. These transferences may be considered wafer indexing operations.

During the operations of FIG. 2, some embodiments may maintain a constant pressure within the processing chamber. As described above, it may not be possible to change the pressure while simultaneously maintaining a plasma, or the plasma may not have desirable characteristics if the pressure is changed while maintaining the plasma. Because of this, the pressure of the processing chamber, either single-station or multi-station, may have constant pressure during operations 203, 205, 207, and 209. For instance, in some embodiments, the pressure of the processing chamber may be lowered to a first pressure before or during operation 201 and the pressure of the processing chamber may remain at that first pressure through the completion operation 209. The pressure in the processing chamber during these operations may be between about 1-10 Torr, for example about 5 Torr or about 2.1 Torr.

The temperature in the reaction chamber during the PECVD reaction and deposition may be between about 50-450° C., in certain embodiments. This range may be especially appropriate for reactions using silane. Where other reactants are used, the temperature range may be more limited or more broad, for example between about 100-450° C. where TEOS is used.

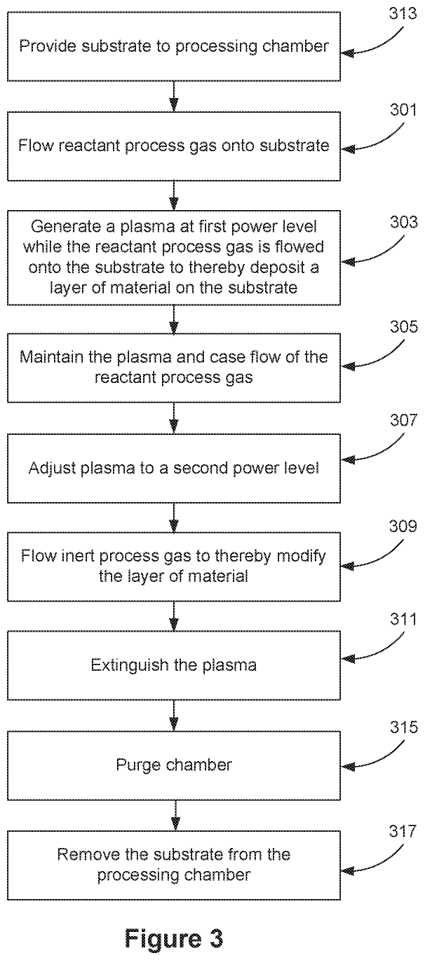

FIG. 3 depicts a second example process flow diagram for performing operations in accordance with disclosed embodiments. Here in FIG. 3, operations 301 through 311 are the same as operations 201 through 211, respectively. In operation 313, a substrate is loaded into the processing chamber. As described above, this includes loading a single substrate into the single station processing chamber as well as loading one or more substrates into the some or all of the stations in a multi-station processing chamber. In some embodiments, this may include loading one substrate into all of the stations in a multi-station processing chamber. Additionally, operation 315 includes a purge operation as described above, which may be performed after the plasma is extinguished in operation 311. In some embodiments, operation 311 and 315 may overlap. After operation 315, the substrate, or substrates, may be removed from the processing chamber as described above. This may include removing all of the substrates from all of the stations in a multi-station processing chamber.

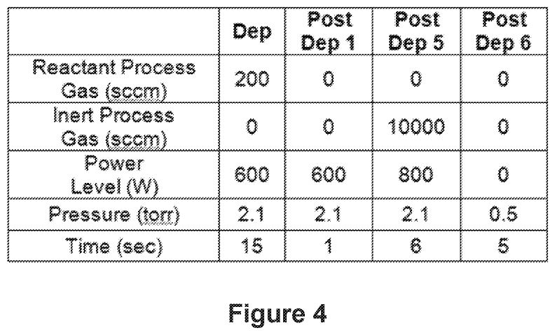

FIG. 4 depicts a table for performing operations in accordance with disclosed embodiments. The table of FIG. 4 is similar to the tab of FIG. 1, but the shaded post-deposition operations Post-Dep 2-4 have been eliminated because these operations are no longer needed in the disclosed embodiments since the plasma is continuously maintained and not extinguished in-between the deposition and post-deposition steps. Here in FIG. 4, the “Dep” column again represents the deposition of the layer of material onto the substrate, which corresponds with operation 203 of FIG. 2. During this Dep operation, the reactant process gas is flowing onto the substrate at a flowrate of 200 sccm, the inert process gas is not flowing onto the substrate, and the power level of the plasma is at the first power level of 600 W. The pressure during this deposition, and the remaining operations, remains constant at 2.1 Torr. In the next column, Post Dep 1, the flow of the reactant process gas is stopped as represented by the “0” flow rate, thus stopping the deposition, while the plasma is maintained and not extinguished, as indicated by the power level of the plasma remaining at 600 W. This column corresponds with operation 205 of FIG. 2.

Here in this embodiment, the process may move directly from Post Dep 1 to Post Dep 5 because the plasma is not turned off, then turned back on, which entails the performance of Post Dep steps 2, 3, and 4 of FIG. 1. Accordingly, the next operation in FIG. 4 is Post Dep 5 in which the inert process gas is flowing onto the substrate and the plasma is still maintained within the processing chamber, but is at a second power level of 800 W. This Post Dep 5 operation modifies the layer of material and corresponds with operation 209 of FIG. 2. The adjustment of the power level from 600 W to 800 W corresponds with operation 207 of FIG. 2. In the Post Dep 6 operation of FIG. 4, the plasma has been extinguished as represented by the “0” in the Power Level box and a purge operation is performed, as indicated by the pressure reduction to 0.5 Torr. The flows of both gases have also been stopped. This operation corresponds with operation 211 and 315 of FIGS. 2 and 3, respectively.

This removal of Post Dep operations 2, 3, and 4 of FIG. 1 thus removes the processing time for these steps, for example, 9.5 seconds, which further results in an overall time reduction of 26% from the process of FIG. 1. In other words, the process time of FIG. 3 is 9.5 seconds less than that of FIG. 1.

### Apparatus

A suitable apparatus for performing the disclosed methods typically includes hardware for accomplishing the process operations and a system controller having instructions for controlling process operations in accordance with the present invention. For example, in some embodiments, the hardware may include one or more PECVD process stations included in a process tool.

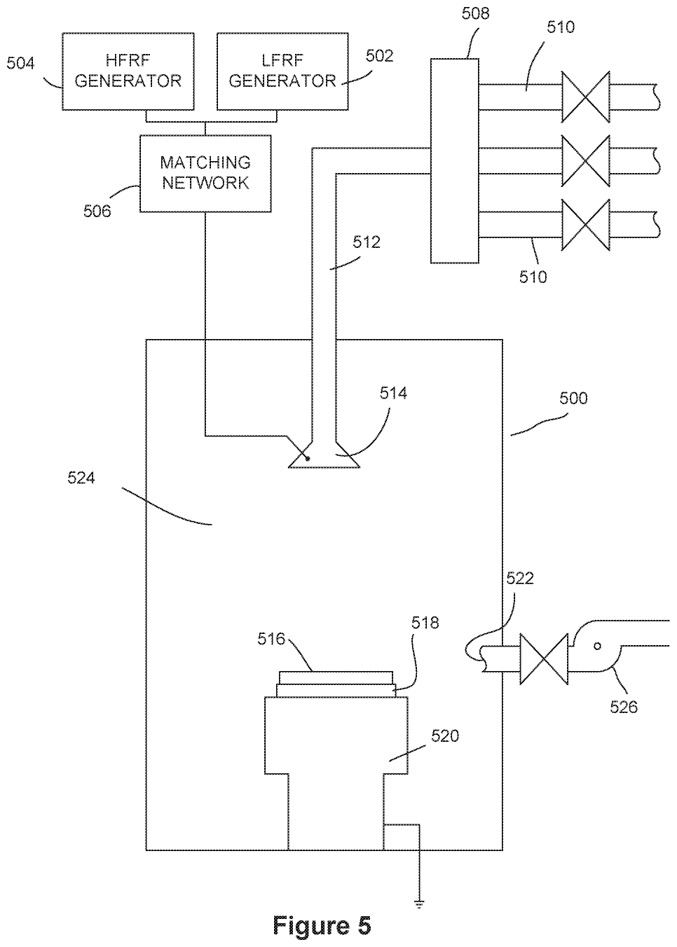

FIG. 5 provides a block diagram of an example apparatus that may be used to practice the disclosed embodiments. As shown, a reactor 500 includes a process chamber 524, which encloses other components of the reactor and serves to contain the plasma generated by, e.g., a capacitor type system including a showerhead 514 working in conjunction with a grounded heater block 520. A high-frequency RF generator 502, connected to a matching network 506, and a low-frequency RF generator 504 are connected to showerhead 514.

The power and frequency supplied by matching network 506 is sufficient to generate a plasma from the process gas, for example 400-700 W total energy. In one implementation of the present invention both the HFRF generator and the LFRF generator may be used during deposition, while is some other implementations just the HFRF generator is used. In a typical process, the high frequency RF component is generally between about 2-60 MHz; in a preferred embodiment, the HF component is about 13.56 MHz. The low frequency LF component is generally between about 250-400 kHz.

Within the reactor, a wafer pedestal 518 supports a substrate 516. The pedestal typically includes a chuck, a fork, or lift pins to hold and transfer the substrate during and between the deposition and/or plasma treatment reactions. The chuck may be an electrostatic chuck, a mechanical chuck or various other types of chuck as are available for use in the industry and/or research.

The process gases are introduced via inlet 512. Multiple source gas lines 510 are connected to manifold 508. The gases may be premixed or not. Appropriate valving and mass flow control mechanisms are employed to ensure that the correct gases are delivered during the deposition and post-deposition phases of the process. In the case that the chemical precursor(s) are delivered in liquid form, liquid flow control mechanisms are employed. The liquid is then vaporized and mixed with other process gases during its transportation in a manifold heated above its vaporization point before reaching the deposition chamber.

Process gases exit chamber 524 via an outlet 522. A vacuum pump 526 (e.g., a one or two stage mechanical dry pump and/or a turbomolecular pump) typically draws process gases out and maintains a suitably low pressure within the reactor by a close loop controlled flow restriction device, such as a throttle valve or a pendulum valve.

The invention may be implemented on a multi-station or single station tool. In specific embodiments, the 300 mm Novellus Vector™ tool having a 4-station deposition scheme or the 200 mm Sequel tool having a 6-station deposition scheme are used.

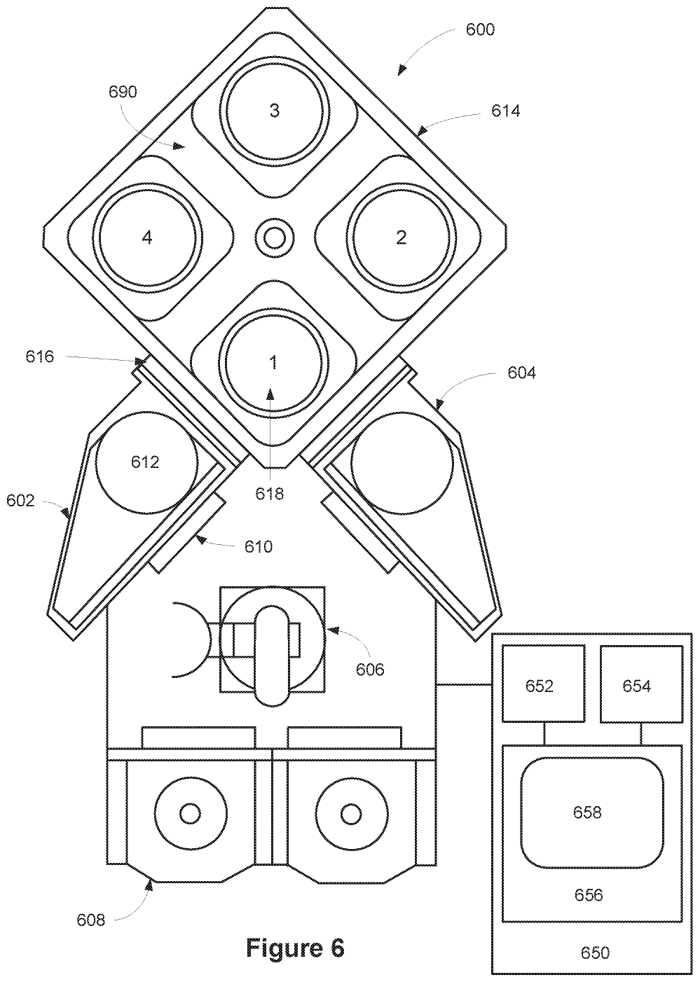

FIG. 6 shows a schematic view of an embodiment of a multi-station processing tool 600 with an inbound load lock 602 and an outbound load lock 604, either or both of which may comprise a remote plasma source. A robot 606, at atmospheric pressure, is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 comprises a remote plasma source, the wafer may be exposed to a remote plasma treatment in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the embodiment depicted in FIG. 6 includes load locks, it will be appreciated that, in some embodiments, direct entry of a wafer into a process station may be provided.

The depicted processing chamber 614 comprises four process stations, numbered from 1 to 4 in the embodiment shown in FIG. 6. Each station has a heated pedestal (shown at 618 for station 1), and gas line inlets. It will be appreciated that in some embodiments, each process station may have different or multiple purposes. While the depicted processing chamber 614 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 also depicts an embodiment of a wafer handling system 690 for transferring wafers within processing chamber 614. In some embodiments, wafer handling system 690 may transfer wafers between various process stations and/or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog and/or digital input/output connections, stepper motor controller boards, etc.

While not shown in FIG. 6, tool 600 may include any feature of tool 500, such as the gases and piping for each station described above, as well as the vacuum pump.

In some embodiments, system controller 650 controls all of the activities of process tool 600. System controller 650 executes system control software 658 stored in mass storage device 654, loaded into memory device 656, and executed on processor 652. System control software 658 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 600. System control software 658 may be configured in any suitable way. For example, various process tool component subroutines or control objects may be written to control operation of the process tool components necessary to carry out various process tool processes in accordance with the disclosed methods. System control software 658 may be coded in any suitable computer readable programming language.

In some embodiments, system control software 658 may include input/output control (IOC) sequencing instructions for controlling the various parameters described above. For example, each PECVD process may include one or more instructions for execution by system controller 650. The instructions for setting process conditions for a PECVD process phase may be included in a corresponding PECVD recipe phase. In some embodiments, the PECVD recipe phases may be sequentially arranged, so that all instructions for a PECVD process phase are executed concurrently with that process phase.

Other computer software and/or programs stored on mass storage device 654 and/or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

The system controller 650, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 650 receives instructions in the form of data, which specify parameters for each of the processing steps to be performed during one or more operations. It should be understood that the parameters may be specific to the type of process to be performed and the type of tool that the controller is configured to interface with or control. Thus as described above, the system controller 650 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In some embodiments, there may be a user interface associated with system controller 650. The user interface may include a display screen, graphical software displays of the apparatus and/or process conditions, and user input devices such as pointing devices, keyboards, touch screens, microphones, etc.

In some embodiments, parameters adjusted by system controller 650 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc.

Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

Although not shown in FIG. 5, tool 500 may include any feature of tool 600, such as the controller 650 and the controller may be configured to execute any instruction described herein for tool 500.

In some embodiments, the controller 650 includes instructions that are configured to execute some or all of the techniques described above. This includes any and all of the operations described above with respect to FIGS. 2 and 3. For instance, the controller includes instructions that are configured to flow the reactant process gas onto a substrate that is supported by the a substrate support, generate, while the reactant process gas is flowed onto the substrate that is supported by the substrate support, the plasma at the first power level in the process station to thereby deposit a layer of a material on the first substrate by PECVD, stop the deposition of the layer of the material on the substrate by ceasing the flow of the reactant process gas onto the substrate, maintain the plasma during and after the deposition is stopped, without extinguishing the plasma, adjust the plasma to a second power level while the plasma is maintained, flow the inert process gas onto the substrate to thereby modify the layer of the material while the plasma is maintained at the second power level, and extinguish the plasma after the layer of the material is modified.

The controller is configured to perform the operations described above in single-station processing chambers, like those of FIG. 5, and multi-station processing chambers, like those of FIG. 6. For example, in the instance in which the apparatus includes two process stations, the controller is configured to simultaneously flow the reactant process gas onto each substrate in both stations, generate, while the reactant process gas is simultaneously flowed onto both substrates, the plasma at the first power level in both process stations to deposit a layer of a material on both substrates by PECVD, stop the deposition of the layer of the material on both substrates by ceasing the flow of the reactant process gas onto both substrates, maintain the plasma during and after the deposition is stopped on both substrates, without extinguishing the plasma, simultaneously flow the inert process gas onto both substrates to thereby modify the layer of the material on both substrates while the plasma is maintained at the second power level, and extinguish the plasma after the layer of the material is modified. Although two stations are described, this operation is applicable to any number of stations in a processing chamber, such as four stations like in the processing chamber of FIG. 6.

The controller is also configured to control the pressure in the processing chamber at a constant pressure while the plasma is generated in the processing chamber, such as 2.1 Torr. The controller is further configured, in some embodiments, to purge the processing chamber after the plasma is extinguished.

### Results

The techniques and apparatuses described above increase throughput, reduce substrate defects, while maintaining desired substrate parameters, such as the desired thickness profile and RI profile. For example, substrate throughput is increased by removing the post-deposition steps that are associated with turning the plasma off after deposition and back on for the post-deposition processing; the removal of these steps reduces the time for the post-deposition processing and therefore reducing the overall substrate processing time. Referring back to FIG. 1, for instance, at least three additional steps (Post Dep 1, Post Dep 2, and Post Dep 3) were performed in order to turn off the plasma after the deposition step which required additional time, such as 9.5 seconds in that example. The removal of these steps removes that associated 9.5 seconds from the overall processing time, thus reducing the processing time and improving throughput. For example, if the overall processing time (which includes the pre-deposition, deposition, and post-deposition processing steps) is 70 seconds, then removing 9.5 seconds is a 13.6% time reduction; if the overall processing time is 43 seconds, then removing 9.5 seconds is a 22% time reduction.

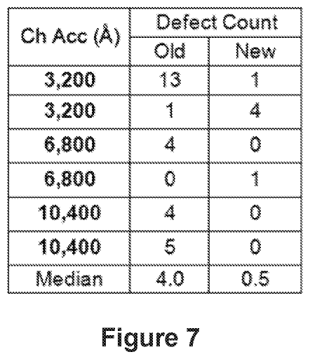

Defects on the substrate were also reduced by removing the post-deposition steps that are associated with turning the plasma off after deposition and back on for the post-deposition processing. FIG. 7 depicts a table of defect counts for processed substrates. The first column represents chamber accumulation in Angstroms during deposition, the middle column shows the number of defects measured on two substrates at various chamber accumulations during deposition of a conventional PECVD process, like that of FIG. 1, and the right column shows the number of defects measured on two substrates at various chamber accumulations during deposition of the PECVD processes in accordance with the embodiments described herein, like that of FIGS. 2 and 4. As can be seen the median number of defects was reduced using the techniques described herein. This defect reduction may be achieved because, in some implementations, continuously maintaining the plasma continuously suspends the unwanted particulates and contaminates in the plasma during the deposition and post-deposition operations which in turn removes the opportunity for the unwanted particulates and contaminates to land on the substrate when the plasma is turned off and collapsed immediately after the deposition, like in Post Dep 2 of FIG. 1.

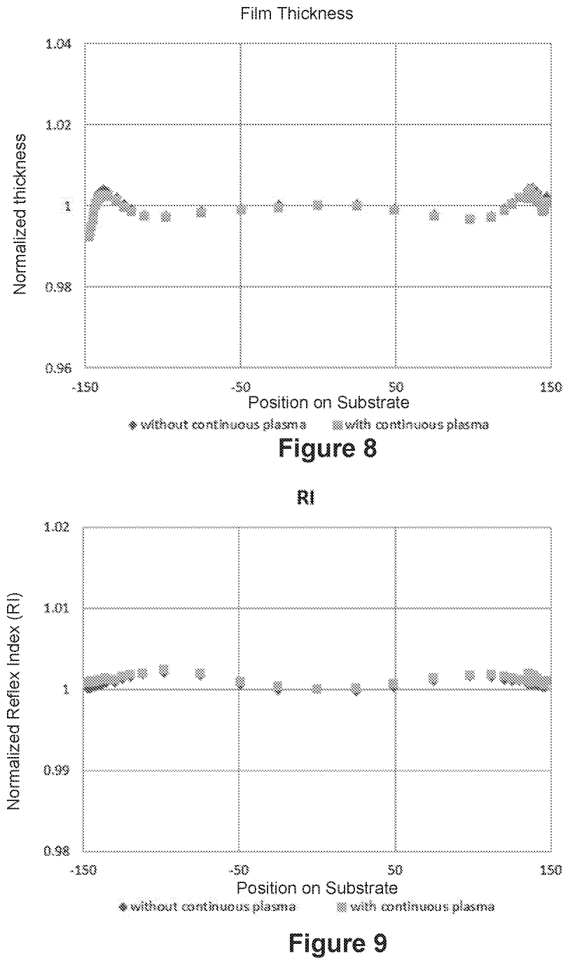

It was also established that the layer of material that was deposited and modified retained its desired properties using the techniques described herein compared to a traditional PECVD process. FIG. 8 depicts film thickness profiles of two processed substrates and FIG. 9 depicts reflective index profiles for the two processed substrates. The vertical axis in FIG. 8 is the normalized thickness and the horizontal axis is position along the substrate with the middle of the axis being the middle of the substrate; similarly the vertical axis in FIG. 9 is the normalized reflective index and the horizontal axis is position along the substrate. In these Figures, a first substrate, represented with the diamonds, was processed using the conventional PECVD deposition and post-deposition process of FIG. 1 that does not have a continuous plasma, and a second substrate was processed using the PECVD deposition and post-deposition process of FIGS. 2 and 3 that utilizes a continuously maintained plasma, represented by the squares, and the resulting layers of material had nearly identical thickness and RI profiles. Accordingly, the techniques described herein are able to reduce substrate processing time and improve throughput, and still maintain the desired material properties, such as film thickness and RI profiles.

While the subject matter disclosed herein has been particularly described with respect to the illustrated embodiments, it will be appreciated that various alterations, modifications and adaptations may be made based on the present disclosure, and are intended to be within the scope of the present invention. It is to be understood that the description is not limited to the disclosed embodiments but, on the contrary, is intended to cover various modifications and equivalent arrangements included within the scope of the claims.

1. A method comprising:
flowing a reactant process gas into a processing chamber containing a substrate;
generating a plasma at a first power level in the processing chamber during the flowing of the reactant process gas, thereby depositing a layer of a material on the substrate by plasma-enhanced chemical vapor deposition;
maintaining the plasma while ceasing flowing the reactant process gas into the processing chamber, thereby stopping the depositing, without extinguishing the plasma;
adjusting the plasma to a second power level;
flowing an inert process gas into the processing chamber, thereby modifying the layer of the material while the plasma is at the second power level; and
extinguishing the plasma after the modifying.

2. The method of claim 1, wherein the second power level is greater than the first power level.

3. The method of claim 2, wherein the first power level is 400 Watts or greater and the second power level is 600 Watts or greater.

4. The method of claim 1, wherein the processing chamber is at a constant pressure while generating the plasma.

5. The method of claim 4, wherein the constant pressure is 2.1 Torr.

6. The method of claim 1, wherein the plasma has a frequency of 13.56 MHz.

7. The method of claim 1, wherein a purging the processing chamber is not performed while generating the plasma.

8. The method of claim 1, further comprising purging the processing chamber after extinguishing the plasma.

9. The method of claim 1, wherein:
flowing the reactant process gas further comprises flowing the reactant process gas into the processing chamber containing a plurality of substrates,
generating the plasma at the first power level further comprises simultaneously depositing the layer of the material on the plurality of substrates by plasma-enhanced chemical vapor deposition,
maintaining the plasma while ceasing flowing the reactant process gas further comprises stopping the depositing on the plurality of substrates without extinguishing the plasma, and
flowing the inert process gas further comprises modifying the layer of the material on the plurality of substrates while the plasma is at the second power level.

10. The method of claim 9, wherein the plurality of substrates are not transferred within the processing chamber during the flowing the reactant process gas, the generating, the maintaining, and the flowing the inert process gas.

11. The method of claim 9, further comprising:
transferring the plurality of substrates into the processing chamber before flowing the reactant process gas, and
transferring the plurality of substrates out of the processing chamber after extinguishing the plasma.

12. The method of claim 1, wherein modifying the layer of the material comprises removing nitrogen bonds, changing a surface roughness of the layer, changing a refractory index of the layer, changing a composition of the layer, and changing a stress of the layer.

13. An apparatus comprising:
a processing chamber;
a first process station that includes a first substrate support, wherein the first substrate support is configured to position a first substrate in the processing chamber;
a process gas unit configured to flow a reactant process gas and an inert process gas onto the first substrate supported by the first substrate support;
a plasma source configured to generate a plasma at a first power level and a second power level in the first process station; and
a controller, wherein the controller includes instructions that are configured to:
flow the reactant process gas onto the first substrate that is supported by the first substrate support,
generate, while the reactant process gas is flowed onto the first substrate that is supported by the first substrate support, the plasma at the first power level in the first process station to thereby deposit a layer of a material on the first substrate by plasma-enhanced chemical vapor deposition (PECVD),
stop the deposition of the layer of the material on the first substrate by ceasing the flow of the reactant process gas onto the first substrate,
maintain the plasma during and after the deposition is stopped, without extinguishing the plasma,
adjust the plasma to a second power level while the plasma is maintained,
flow the inert process gas onto the first substrate to thereby modify the layer of the material while the plasma is maintained at the second power level, and
extinguish the plasma after the layer of the material is modified.

14. The apparatus of claim 13, wherein the first power level is 400 Watts or greater and the second power level is 600 Watts or greater.

15. The apparatus of claim 13, further comprising a vacuum pump configured to control a pressure in the processing chamber, wherein the controller further includes instructions that are configured to maintain the processing chamber at a constant pressure while the plasma is generated in the processing chamber.

16. (canceled)

17. The apparatus of claim 15, wherein:
the vacuum pump is further configured to evacuate the processing chamber, and
the controller further includes instructions that are configured to purge the processing chamber after the plasma is extinguished.

18. The apparatus of claim 13, wherein the plasma source is configured to generate the plasma at a frequency of 13.56 MHz.

19. The apparatus of claim 13, further comprising a second process station, wherein:
the second process station includes a second substrate support, wherein the second substrate support is configured to position a second substrate in the processing chamber,
the process gas unit is further configured to flow the reactant process gas and the inert process gas onto the second substrate supported by the second substrate support,
the plasma source is further configured to generate the plasma in the second process station, and
the controller further includes instructions that are configured to:
simultaneously flow the reactant process gas onto the first substrate and the second substrate that is supported by the second substrate support,
generate, while the reactant process gas is simultaneously flowed onto the first substrate and the second substrate, the plasma at the first power level in the first process station and in the second process station to thereby deposit a layer of a material on the first substrate and on the second substrate by PECVD,
stop the deposition of the layer of the material on the first substrate and the second substrate by ceasing the flow of the reactant process gas onto the first substrate and onto the second substrate,
maintain the plasma during and after the deposition is stopped on the first substrate and onto the second substrate, without extinguishing the plasma,
simultaneously flow the inert process gas onto both the first substrate and onto the second substrate to thereby modify the layer of the material on the first substrate and the second substrate while the plasma is maintained at the second power level, and
extinguish the plasma after the layer of the material is modified.

20. The apparatus of claim 13, wherein the reactant process gas comprises one of a silicon, a silane, a tetra-ethoxy-silane, and a tetra-methyl-silane.

21.-23. (canceled)

24. The apparatus of claim 13, wherein the inert process gas comprises N2O.
